(19) United States
(12) Patent Application Publication
(10) Pub. No.: US 2010/0314777 A1
(43) Pub. Date: Dec. 16, 2010

(54) Semiconductor device and method for manufacturing same

(75) Inventor: Noriaki Oda, Ibaraki (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki-shi (JP)

(21) Appl. No.: 12/662,772

(22) Filed: May 3, 2010

(30) Foreign Application Priority Data
Jun. 15, 2009 (JP) 2009-142215

(51) Int. Cl. H01L 23/522; H01L 21/768

(52) U.S. Cl. 257/774; 438/618; 257/E23.145; 257/E21.585

(57) ABSTRACT

A semiconductor device includes: a semiconductor substrate; an interlayer insulating film provided on the semiconductor substrate; an interconnect (second interconnect trench) composed of a metallic film provided in an interconnect trench (second copper interconnect) and a plug composed of a metallic film provided in a connection hole (via hole) coupled to the second interconnect trench, both of which are provided in the interlayer insulating film; a first sidewall provided on a side surface of the via hole; and a second sidewall provided on a side surface of the second interconnect trench, and a thickness of the first sidewall in vicinity of a bottom of the side surface of the via hole is larger than a thickness of the second sidewall in vicinity of a bottom of the second interconnect trench.

The present application is based on Japanese patent application No. 2009-142,215, the content of which is incorporated hereinto by reference.

### BACKGROUND

1. Technical Field

The present invention relates to a semiconductor device and a method for manufacturing thereof.

2. Background Art

In a multiple-layered interconnect structure of a conventional semiconductor device, copper interconnects and low dielectric constant (low-k) interlayer insulating films are employed. As the generation of semiconductor devices is advanced to provide further miniaturization of patterns, following problems are arisen. More specifically, increased parasitic capacitance or increased parasitic resistor of an interconnect adversely affects a circuit operating speed of the semiconductor device. In addition, increased parasitic capacitance causes increased electric power consumption.

In order to reduce such deterioration of the circuit operating speed and the increase of the power consumption, a porous low dielectric constant film having lower dielectric constant (porous low-k film) has been employed for an interlayer insulating film (Japanese Patent Laid-Open No. 2005-183,779). However, a damage is easily generated in the porous low-k film when a reactive ion etching process is conducted for creating a trench for forming an interconnect or subsequent ashing process is conducted for stripping a resist.

Such damage may result in an increase in the leakage current between interconnects or a deterioration in the dielectric withstand voltage. Therefore, a structure called as “sidewall”, which is composed of a non-porous protective film, is adopted for a protective film covering a trench or side surfaces of a via hole. Even if a small damage is caused in the porous low-k film, such structure prevents an increase in the leakage current between interconnects or a deterioration in the dielectric withstand voltage, which are caused by such damage.

For example, Japanese Patent Laid-Open No. H10-284,600 discloses a semiconductor device as shown in FIG. 15, in which side surfaces of an interconnect trench and a via hole are covered with sidewalls composed of an insulating film. In such semiconductor device, a sidewall 107 is formed on a side surface of a via hole 106, and a sidewall 109 is formed on a side surface of an interconnect trench 108 (FIG. 15.) According to Japanese Patent Laid-Open No. H10-284,600, the sidewalls 107 and 109 are formed simultaneously on the side surface of the via hole and on the side surface of the upper layer interconnect trench in one process, respectively. Therefore, it is difficult to separately control each of the thicknesses of the sidewalls 107 and 109. In addition, the sidewall 107 and the sidewall 109 have substantially the equivalent thicknesses at least in the bottom surface.

United States Patent Application Publication No. 20020192937-A1 discloses a manufacturing process for forming a sidewall composed of an insulating film on an outer wall of an interconnect trench. U.S. Pat. No. 7,169,698 discloses a semiconductor device, in which sidewalls are disposed on side surfaces of an interconnect trench and a via hole. Such sidewalls are utilized sacrificial films for preventing a deformation in the shape during an etching process for an organic compound insulating film. No description is made on the difference in the thickness between the sidewall within the via hole and the sidewall within the interconnect trench in U.S. Pat. No. 7,169,698. Japanese Patent Laid-Open No. 2000-164,707 discloses a semiconductor device, in which multiple-layered anti-oxidation films are provided on side surfaces of an interconnect trench and a connection hole.

Progressed miniaturization of the devices causes the via hole extending beyond an interconnect disposed above the via hole or an interconnect disposed under the via hole, causing reduced distances between the via hole and an adjacent interconnect, which may lead to phenomena such as an increase in leakage current deterioration of dielectric withstand voltage and the like. More specifically, since the radius of curvature of the via hole is smaller than that of the interconnect trench, the coverage of the sidewall of the insulating film coating the via hole is easily reduced. Moreover, when a potential difference is generated between the via hole and the adjacent interconnect, a concentration of electric field is easily occurred in the portion where the via hole extends beyond the interconnect.

In such condition, if the concentration of the electric field is occurred in the protruded portion of the upper layer interconnect extending upwardly from the via hole, in particular in the upper portion thereof, a leakage of electric current or a deteriorated dielectric withstand voltage may be easily generated in such portion.

The conventional technology as disclosed in the above-described patent documents have the following problems.

First, if the thickness of the sidewall is reduced so as to prevent the via hole from extending beyond the interconnect in view of avoiding a concentration of electric field, acceleration of an increase in the leakage current and a deterioration in the dielectric withstand voltage are eventually occurred. Second, if the entire thickness of the sidewall including the side surfaces of the interconnect trench and the via hole is increased in order to improve the prevention of the leakage current and the dielectric withstand voltage, an increase in the interconnect capacitance and an increase in delay time for signal propagation through the interconnect are occurred. While the above descriptions are made in reference to examples of the porous low-k film, such problems are not particularly limited thereto, and similar problems may be occurred with general low dielectric constant films.

### SUMMARY

According to one aspect of the present invention, there is provided a semiconductor device, including: a substrate; an interlayer insulating film provided over the substrate; an interconnect composed of a metallic film provided in an interconnect trench and a plug composed of a metallic film provided in a connection hole coupled to the interconnect trench, the interconnect and the plug being provided in the interlayer insulating film; a first sidewall provided over a side surface of the connection hole; and a second sidewall provided over a side surface of the interconnect trench, wherein a thickness of the first sidewall in vicinity of a bottom of the side surface of the connection hole is larger than a thickness of the second sidewall in vicinity of a bottom of the side surface of the interconnect trench.

According to another aspect of the present invention, there is provided a method for manufacturing a semiconductor device, including: forming an interlayer insulating film over a substrate; forming an interconnect trench and a connection hole coupled to the interconnect trench in the interlayer insulating film; forming a first sidewall over a side surface of the connection hole and forming a second sidewall over a side surface of the interconnect trench; and forming a metallic film in the interconnect trench and in the connection hole, wherein the forming the first and the second sidewalls includes forming the sidewalls so that a thickness of the first sidewall in vicinity of a bottom of the side surface of the connection hole is larger than a thickness of the second sidewall in vicinity of a bottom of the side surface of the interconnect trench.

In such configuration, the first sidewall of the via hole may be formed to have a thickness, which is larger than the thickness of the second sidewall of the interconnect trench. Thus, the larger thickness of the first sidewall of the via hole provides a prevention for an increase of the leakage current to avoid a deterioration of the dielectric withstand voltage, and the smaller thickness of the entire second sidewall of interconnect trench provides reduced parasitic capacitance between the interconnects.

According to the present invention, a semiconductor device with improved reliability is presented.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view, schematically illustrating a semiconductor device in an embodiment according to the present invention;

FIGS. 2A and 2B are cross-sectional views, schematically illustrating a procedure for manufacturing a semiconductor device in an embodiment according to the present invention;

FIGS. 3A and 3B are cross-sectional views, schematically illustrating the procedure for manufacturing the semiconductor device in an embodiment according to the present invention;

FIGS. 4A and 4B are cross-sectional views, schematically illustrating the procedure for manufacturing the semiconductor device in an embodiment according to the present invention;

FIGS. 5A and 5B are cross-sectional views, schematically illustrating the procedure for manufacturing the semiconductor device in an embodiment according to the present invention;

FIGS. 6A and 6B are cross-sectional views, schematically illustrating the procedure for manufacturing the semiconductor device in an embodiment according to the present invention;

FIG. 7 is a cross-sectional view, schematically illustrating a semiconductor device in an embodiment according to the present invention;

FIGS. 8A and 8B are cross-sectional views, schematically illustrating a procedure for manufacturing a semiconductor device in an embodiment according to the present invention;

FIGS. 9A and 9B are cross-sectional views, schematically illustrating the procedure for manufacturing the semiconductor device in an embodiment according to the present invention;

FIGS. 10A and 10B are cross-sectional views, schematically illustrating the procedure for manufacturing the semiconductor device in an embodiment according to the present invention;

FIGS. 11A and 11B are cross-sectional views, schematically illustrating the procedure for manufacturing the semiconductor device in an embodiment according to the present invention;

FIGS. 12A and 12B are cross-sectional views, schematically illustrating the procedure for manufacturing the semiconductor device in an embodiment according to the present invention;

FIG. 13 includes a graph showing an evaluation of TDDB (time dependent dielectric breakdown) and a schematic diagram of a pattern utilized for the TDDB evaluation;

FIG. 14 is a schematic diagram, useful in describing an effect of the embodiment according to the present invention; and

FIG. 15 is a cross-sectional view, schematically illustrating a conventional semiconductor device.

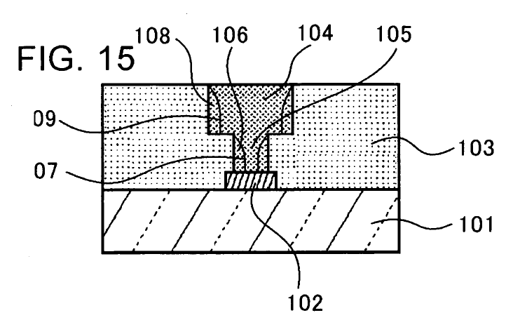

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Exemplary implementations according to the present invention will be described in detail as follows in reference to the annexed figures. In all figures, an identical numeral is assigned to an element commonly appeared in the figures, and the detailed description thereof will not be repeated.

### First Embodiment

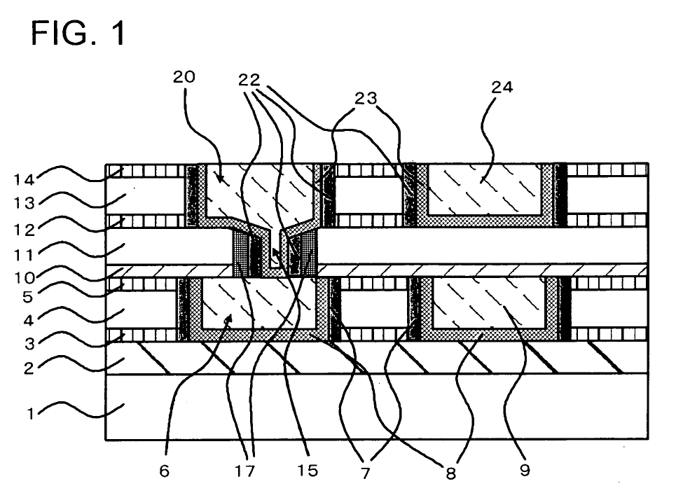

FIG. 1 schematically illustrates a cross-sectional view of a semiconductor device of first embodiment. In this embodiment, transistors and the like, which are not shown, are formed on a semiconductor substrate 1. The semiconductor device according to the present embodiment includes: a substrate (semiconductor substrate 1.); an interlayer insulating film provided on the semiconductor substrate 1; an interconnect (second interconnect trench 20) composed of a metallic film provided in an interconnect trench (second copper interconnect 24) and a plug composed of a metallic film provided in a connection hole (via hole 15) coupled to the second interconnect trench 20, both of which are provided in the interlayer insulating film; a first sidewall (first sidewall 17 and second sidewall 22) provided on a side surface of the via hole 15; and a second sidewall (second sidewall 22) provided on a side surface of the second interconnect trench 20, and a thickness of the first sidewall (first sidewall 17 and second sidewall 22) in vicinity of a bottom of the side surface of the via hole 15 is larger than a thickness of the second sidewall (second sidewall 22) in vicinity of a bottom of the second interconnect trench 20.

As shown in FIG. 1, the first interlayer insulating film 2 is formed on the semiconductor substrate 1 (silicon substrate). A first etch stop film 3, a second interlayer insulating film 4 and a first cap insulating film 5 are formed in this sequence on the first interlayer insulating film 2. A first interconnect trench 6 is partially formed in these interlayer insulating films (here, a mark of an arrow in the tip in the diagram indicates a trench or a hole). A first copper interconnect 9 is formed in the first interconnect trench 6 through a first barrier metal 8 serving as a liner. In addition, a sidewall 7 serving as a first layer is formed on the side surface of the first interconnect trench 6. More specifically, the sidewall 7 serving as the first layer is formed between the second interlayer insulating film 4 and the first barrier metal 8.

In addition, an second etch stop film 10, a via interlayer insulating film 11, a third etch stop film 12, a third interlayer insulating film 13 and a second cap insulating film 14 are formed over immediately above of the first copper interconnect 9 sequentially from the bottom (FIG. 1). A via hole 15 is partially formed in the via interlayer insulating film 11. A second interconnect trench 20 is formed in the third interlayer insulating film 13. A second copper interconnect 24 is formed in the inside of the via hole 15 and the second interconnect trench 20 through the second barrier metal 23 serving as a liner.

In this embodiment, the via hole 15 and the second copper interconnect 24 are integrally formed to be a single body by so-called dual damascene process.

As shown in FIG. 1, the first sidewall 17 and the second sidewall 22 are formed on the side surface of the via hole 15. On the other hand, the second interconnect trench 20 is provided with the second sidewall 22 formed thereon. More specifically, the first sidewall 17 and the second sidewall 22 are formed between the via interlayer insulating film 11 and the second barrier metal 23. In such case, the second sidewall 22 is formed to be disposed radially inward of the first sidewall 17 in the via hole 15. The second sidewall 22 is also formed between the third interlayer insulating film 13 and the second barrier metal 23.

As described above, in the semiconductor device of the present embodiment, the thickness of a sidewall of via hole 15 (the total thickness of the first sidewall 17 and the second sidewall 22) is thicker than the thickness of the second sidewall 22 of the second interconnect trench 20. In such case, the comparison of the thickness of the bottom leastwise provides the result that the thickness of the sidewall of the via hole 15 is larger.

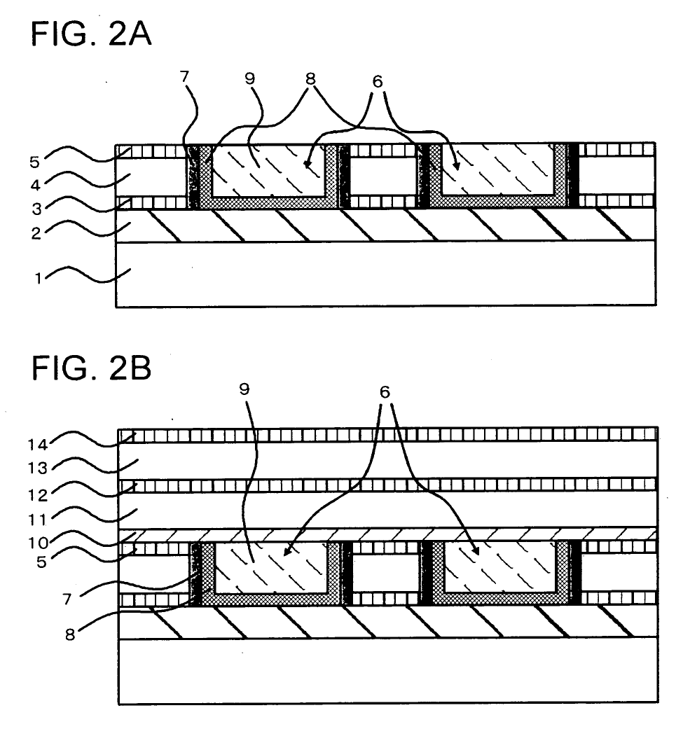

Next, a method for manufacturing the semiconductor device of first embodiment will be described in reference to FIGS. 2A to 6B. FIGS. 2A and 2B, FIGS. 3A and 3B, FIGS. 4A and 4B, FIGS. 5A and 5B, and FIGS. 6A and 6B are cross-sectional views, schematically illustrating a procedure for manufacturing a semiconductor device in first embodiment.

A method for manufacturing the semiconductor device according to the present embodiment includes forming an interlayer insulating film on a substrate (semiconductor substrate 1), forming an interconnect trench (second interconnect trench 20) and a connection hole (via hole 15) coupled to the second interconnect trench 20 in the interlayer insulating film, forming a first sidewall (first sidewall 17 and second sidewall 22) on a side surface of the via hole 15 and forming a second sidewall (second sidewall 22) on a side surface of the second interconnect trench 20, forming a metallic film (second barrier metal 23) in the inside of the second interconnect trench 20 and in the inside of the via hole 15, in which a thickness of the first sidewall (first sidewall 17 and second sidewall 22) in vicinity of a bottom of the side surface of the via hole 15 is larger than a thickness of the second sidewall (second sidewall 22) in vicinity of a bottom of the side surface of the second interconnect trench 20. In the present embodiment, the above-described interlayer insulating film is composed of the first interlayer insulating film (via interlayer insulating film 11) and the second interlayer insulating film (third interlayer insulating film 13) provided on the via interlayer insulating film 11. The via hole 15 is also provided in the via interlayer insulating film 11, and the second interconnect trench 20 is provided in the third interlayer insulating film 13.

First of all, an active device such as a transistor and the like and a passive device such as a capacitance resistor and the like are formed on the semiconductor substrate 1. In order to electrically insulate the portions of the elements and the interconnects except the contact conducting portions, the first interlayer insulating film 2 is deposited as shown in FIG. 2A. A phosphosilicate glass (PSG) film having a thickness of 200 nm to 800 nm is employed for the first interlayer insulating film 2, and the film is deposited via a plasma chemical vapor deposition (plasma CVD) process. A silicon carbonitride (SiCN) film having a thickness of 20 nm to 70 nm as the first etch stop film 3 and a porous carbon containing silicon oxide film (porous SiOCH: porous low-k film) having a thickness of 80 nm to 150 nm as the second interlayer insulating film 4 are deposited in this sequence on or over the first interlayer insulating film 2 via a chemical vapor deposition (CVD) process. (the range of the value presented in the entire Description include the values of the upper end and the lower end of the presented range, respectively.)

Subsequently, the second interlayer insulating film 4 is irradiated with, for example, ultra-violet ray containing a wavelength range of 200 nm to 500 nm under a condition of a substrate temperature of 350 degrees Celsius (degrees C.) to 420 degrees C. The radiation with ultraviolet ray provides strengthened skeleton structure composed of Si—O—Si in the porous low-k film, and simultaneously allows accelerating an elimination of a porogen composed of C-Hn.

Subsequently, SiOC having a thickness of 10 nm to 50 nm as the first cap insulating film 5 is deposited on the second interlayer insulating film 4 via a plasma CVD. Then, a photolithographic process, a reactive dry etching process and an ashing process are conducted. This allows forming the first interconnect trench 6 having a desired pattern in the first etch stop film 3, the first cap insulating film 5 and the second interlayer insulating film 4. Then, a silicon oxycarbide (SiOC) having an average thickness of 10 nm to 40 nm is deposited, and then an etchback process is conducted to form an SiOC film of 2 nm to 20 nm for the first layer of the sidewall 7 on or over the side surface in the inside of the first interconnect trench 6. The interior thereof is further filled with the first barrier metal 8 and the first copper interconnect 9 (FIG. 2A). Here, tantalum (Ta) is employed for the first barrier metal 8.

Subsequently, as shown in FIG. 2B, An SiCN film having a thickness of 20 nm to 70 nm as the second etch stop film 10 and a SiOCH film having a thickness of 50 nm to 120 nm as the via interlayer insulating film 11 are deposited in this sequence on or over the first interconnect trench 6. Then, a SiCN film of 20 nm to 70 nm serving as the third etch stop film 12 is deposited, and a porous silicon oxycarbide (SiCOH) film of 50 nm to 120 nm serving as the third interlayer insulating film 13 is deposited. Further, a SiOC film of 30 nm to 60 nm serving as the second cap insulating film 14 is deposited on or over the third interlayer insulating film 13 via a plasma CVD process.

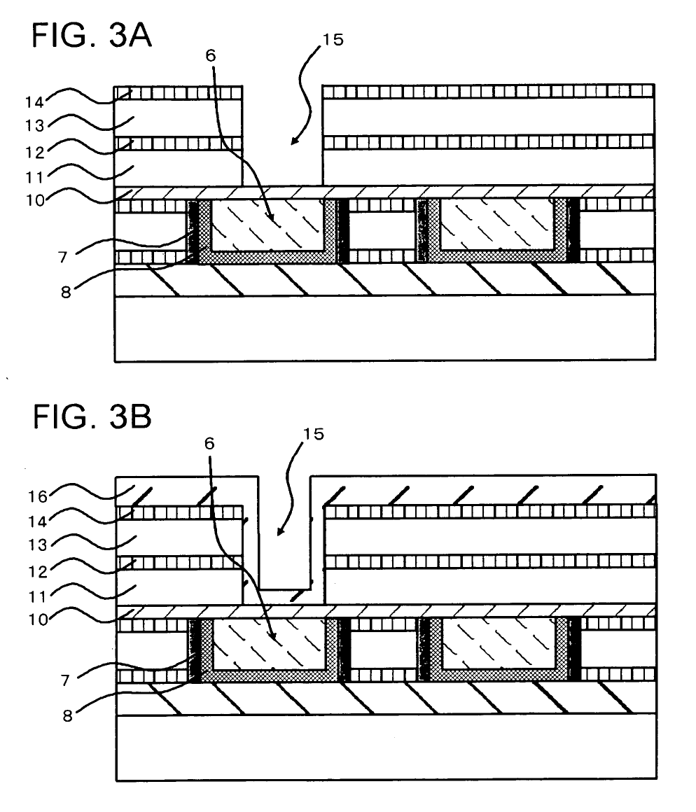

Subsequently, as shown in FIG. 3A, a photolithographic process and a reactive dry etching process are carried out to selectively open to form the first via hole 15, so that the hole terminate within the etch stop film layer 10. In such configuration, the via hole 15 extends through the second cap insulating film 14, the third interlayer insulating film 13, the third etch stop film 12 and the via interlayer insulating film 11. More specifically, the via hole 15 is formed over the first copper interconnect 9 in the first interconnect trench 6, so as to overlap thereof in vertical view according to the surface of the substrate.

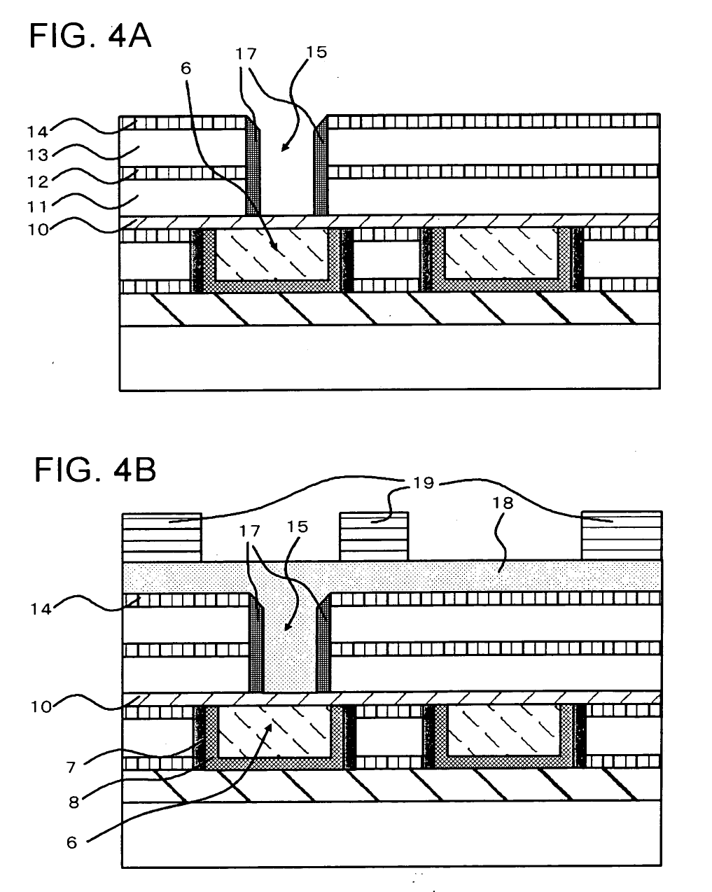

Subsequently, as shown in FIG. 3B, an SiOC film serving as an insulating film 16 for forming the first sidewall is deposited in the inside of the via hole 15 and on the second cap insulating film 14 so as to have an average thickness of 10 nm to 50 nm in the via hole 15. Subsequently, as shown in FIG. 4A, the insulating film 16 for forming the first sidewall is etched back. This allows forming the first sidewall 17 composed of SiOC film having an average thickness of 3 nm to 40 nm in the via hole 15 (portion remained through the etchback process for the insulating film 16 for forming sidewall). In such case, the circumference of the upper portion of the first sidewall 17 is tapered.

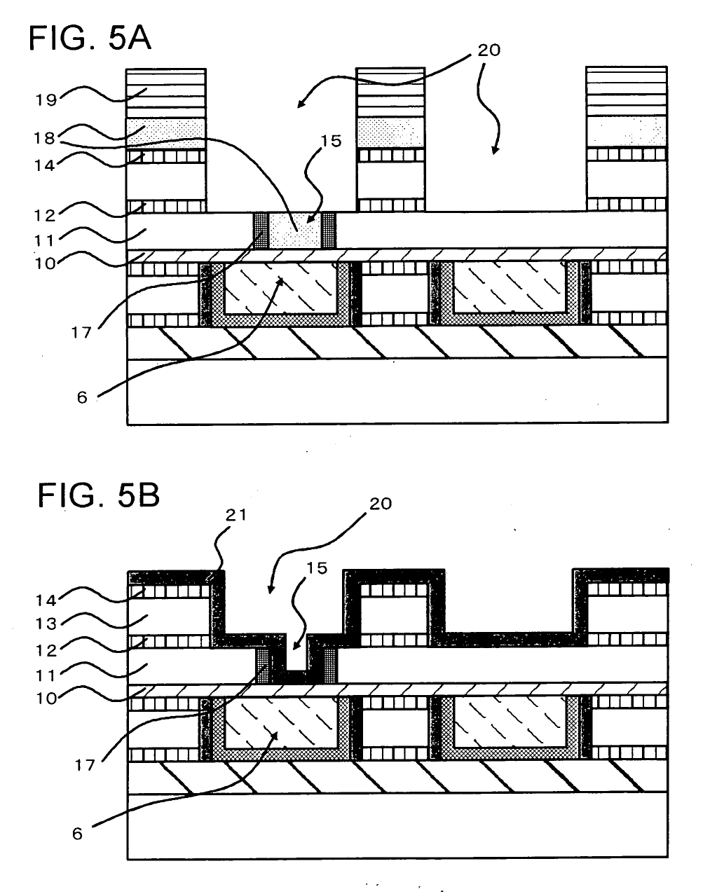

Then, as shown in FIG. 4B, a buried material 18 fills the interior of the via hole 15 and cover over the second cap insulating film 14. An organic material-based coating film, for example, is employed for the buried material 18. A photo resist film is formed over the buried material 18, and then the resist is partially removed to leave a photo resist 19 for forming the second interconnect trench so as to expose an area dedicated for forming the second interconnect trench 20. In this stage, the opening pattern of the photo resist 19 is provided so as to dispose the via hole 15 in the position where the first copper interconnect 9 overlaps with the second copper interconnect 24 in the subsequent processes. Then, as shown in FIG. 5A, the second interconnect trench 20 is selectively removed, and the etching process is stopped before etching through the third etch stop film 12.

Then, as shown in FIG. 5B, the buried material 18 and the photo resist 19 are removed. Then, an insulating film 21 for forming the second sidewall having a thickness of 10 nm to 50 nm is deposited over the second cap insulating film 14 and in the interior of the second interconnect trench 20 and the via hole 15.

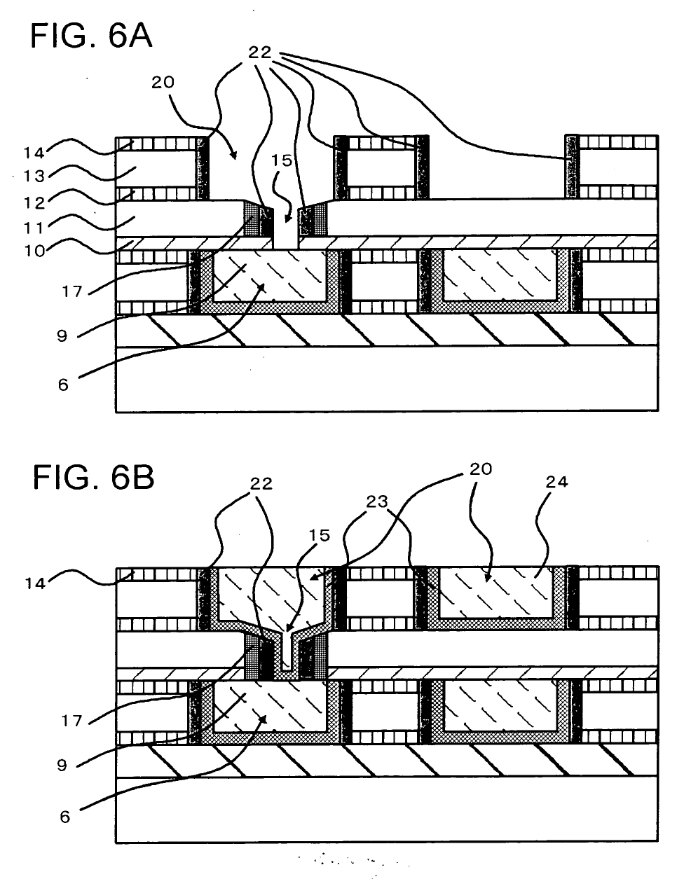

Then, as shown in FIG. 6A, the insulating film 21 for forming the second sidewall is etched back via a reactive ion etching process. This allows forming the second sidewall 22 over the side surface of the second interconnect trench 20 and over the side surface of the via hole 15, Average thicknesses of the eventually-obtained side surface portions of the second sidewall 22 is 3 nm to 40 nm for the portion over the first via hole 15, and 2 nm to 20 nm for the portion over the second interconnect trench 20. In such case, the circumference of the upper portion of the second sidewall 22 in the via hole 15 is tapered.

In this way, a multiple-layered structure serving as the sidewall in via hole 15, which includes the second sidewall 22 deposited on the first sidewall 17, is obtained. Thus, these sidewalls are formed so that the thickness of a sidewall of via hole 15 (the total thickness of the first sidewall 17 and the second sidewall 22) is thicker than the thickness of the second sidewall 22 of the second interconnect trench 20. In such case, these sidewalls are formed so that the comparison of the thickness of the bottom leastwise provides the result that the thickness of the sidewall of the via hole 15 is larger.

Hereafter, the second barrier metal 23 is formed so as to cover the inner surfaces of via hole 15 and the second sidewall 22. Here, Ta is employed for the second barrier metal 23. Then, a copper (Cu) seed layer is formed to bury the via hole 15 and the second sidewall 22, and then a plating process is conducted to form a copper film. Hereafter, excess metal formed outside of the second interconnect trench 20 is removed via a chemical mechanical polishing (CMP) process to form the second copper interconnect 24. In this way, a multiple-layered interconnect structure including the first copper interconnect 9 and the second copper interconnect 24, which are coupled through the via hole 15, is obtained (FIG. 6B). The semiconductor device having the dual-layered interconnect structure as shown in FIG. 1 is obtained by the above-described process.

Next, advantageous effects of the present embodiment will be described. In the present embodiment, the sidewalls may be formed so that the thickness of the sidewall in the via hole 15 is larger than the thickness of the second sidewall 22 of the second interconnect trench 20. In addition, since the sidewall in the via hole 15 may be composed of the multiple-layered structure of the first sidewall 17 and the second sidewall 22, only the thickness of the sidewall in the via hole 15 (first sidewall 17) can be increased while reducing the thickness of the second sidewall 22 of the second interconnect trench 20. Thus, the increased thickness of the sidewall in the via hole 15 provides a prevention for an increase of the leakage current to avoid a deterioration of the dielectric withstand voltage. The smaller thickness of the entire second sidewall of interconnect trench provides reduced parasitic capacitance between the interconnects.

In addition, since the thickness of the second sidewall 22 in the entire second interconnect trench 20 can be reduced, an occupancy ratio of the portion of the sidewall having higher specific dielectric constant over the space can be reduced when a constant linewidth is formed to increase the ratio of the low dielectric constant film, resulting in reduced parasitic capacitance between the interconnects. As described above, the semiconductor device exhibiting improved reliability can be achieved.

In the present embodiment, a dense insulating film, preferably an insulating film without containing a pore, may be employed for the sidewall. Therefore, a reduced leakage current and an improved dielectric withstand voltage can be achieved. On the other hand, since such dense sidewall exhibits higher dielectric constant, the thickness of the sidewall over the entire side surface of the interconnect trench is reduced. This allows reducing the occupancy ratio of the portion of the sidewall having higher specific dielectric constant over the space. This results in reducing an increase in the interconnect capacitance and reducing the signal propagation delay time through the interconnect in the present embodiment.

In the present embodiment, in view of reducing a deterioration in the circuit operating speed and an increase in the power consumption, a porous low dielectric constant film (porous low-k film) having lower dielectric constant, preferably having a dielectric constant of equal to or lower than 3, is employed for the interlayer insulating film (the first interlayer insulating film 2, the second interlayer insulating film 4 and the third interlayer insulating film 13). In such case, the side surface of the interlayer insulating film is protected by the sidewall. Thus, even if some damages are generated over the side surface of the interlayer insulating film during a reactive ion etching process or a subsequent ashing process for stripping the resist film in the process for creating the interconnect trench and the like, an increase in the leakage current or a deterioration in the dielectric withstand voltage between the interconnects resulted from such damage can be avoided. This is resulted by an effect of covering the outside of the interlayer insulating film having a damage or more specifically the portion contacting with the trench interconnect by the sidewall (chemically stable film) that is more dense than the interlayer insulating film. The damage as being referred to in this description means a reduced strength or density of chemical bond (Si—O—Si bond) that dominates the density of the entire film or constitutes the film by eliminating carbon from the porous low-k film.

In the present embodiment, as shown in FIG. 1, the circumference of the upper portion of the sidewall in the via hole 15, or more specifically the circumference of the upper portion of the first sidewall 17 and the second sidewall 22, is tapered. This allows providing an improved coverage of the second barrier metal 23 over the sidewall in the via hole 15. Thus, the semiconductor device exhibiting improved reliability can be achieved. In addition, a manufacture allowance of the present embodiment can be improved.

According to the operation of the present embodiment, the conformal second sidewall 22 is formed over the side surface of the second interconnect trench 20. In such case, a cross-sectional geometry of the second sidewall 22 represented in the upper portion of the side surface of the second interconnect trench 20 includes a corner. The cross-sectional feature of the second sidewall 22 along the line normal to the substrate may be at least partially tapered. In addition, at least a certain thickness of the second sidewall 22 is ensured through the side surface of the second interconnect trench 20 from the upper end portion to the bottom end portion. Therefore, as shown in FIG. 1, it is configured that the second sidewall 22 is provided between the second barrier metal 23 and a multiple-layered structure composed of the third etch stop film 12, the third interlayer insulating film 13 and the second cap insulating film 14. This allows preventing the second barrier metal 23 from reacting with water mainly contained in the third interlayer insulating film 13. This also allows preventing a degradation of the coverage over the barrier metal or the copper interconnect may be caused during the deposition of the second barrier metal 23 mainly due to a degas from the third interlayer insulating film 13. In this way, the semiconductor device exhibiting improved reliability can be achieved.

### Second Embodiment

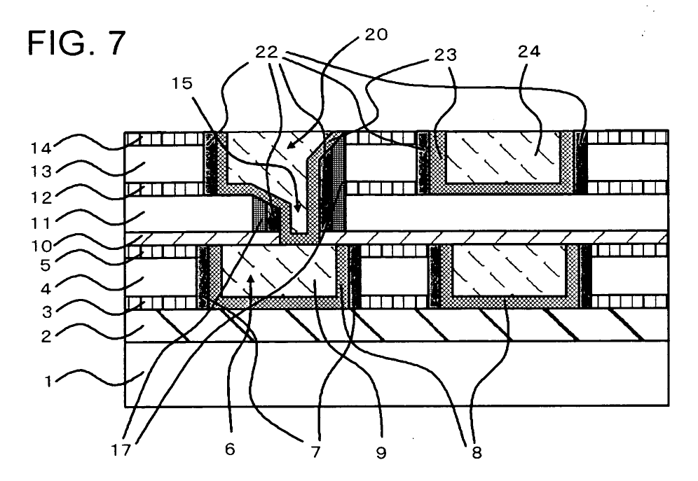

A semiconductor device of second embodiment will be described in reference to FIG. 7. FIG. 7 schematically illustrates a cross-sectional view of a semiconductor device of second embodiment. The device according to second embodiment is similar as the device of first embodiment, except that the positional relation of the via hole 15 and the second interconnect trench 20 is different. In the second embodiment, as shown in FIG. 7, an end of the via hole 15 is protruded outside of an end of the second layer interconnect (second interconnect trench 20) due to an misalignment or the like. More specifically, in comparison with the device of first embodiment shown in FIG. 1, the first sidewall 17 is formed to be disposed radially outward of the second sidewall 22 in the second interconnect trench 20.

As shown in FIG. 7, a portion of the first sidewall 17 shares a portion of the second sidewall 22, which serves as the sidewall of the via hole 15 and the second interconnect trench 20. In addition, the via hole 15 and the second interconnect trench 20 are composed of substantially the same surface (an inner surface of the first sidewall 17). In addition, a radius of curvature of the via hole 15 viewed along the direction perpendicular to the substrate is substantially the same as that of the second interconnect trench 20.

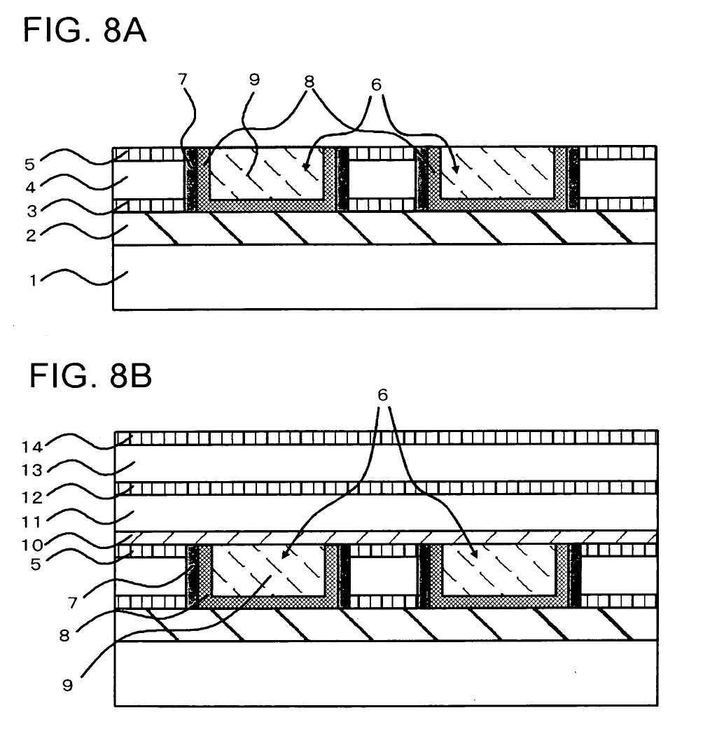

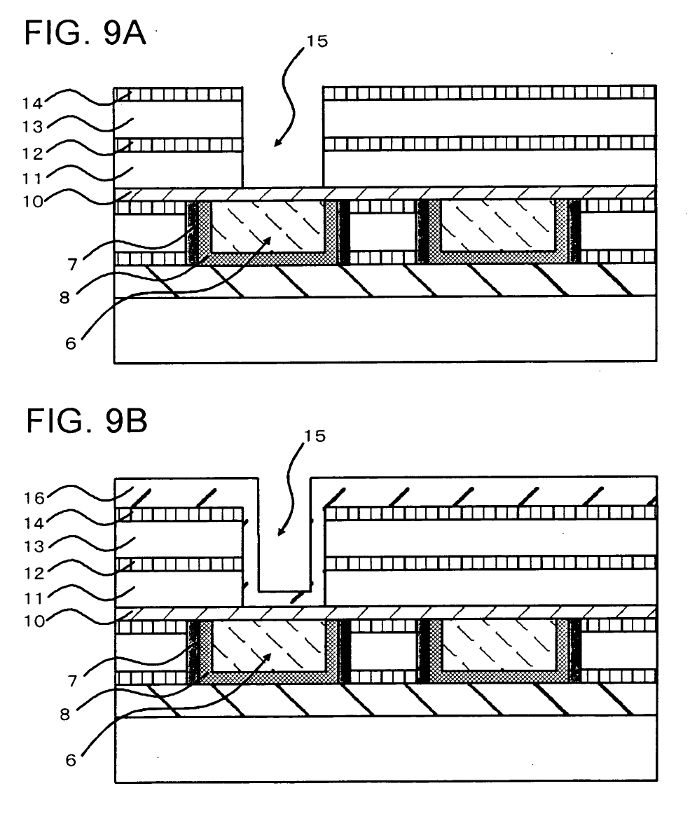

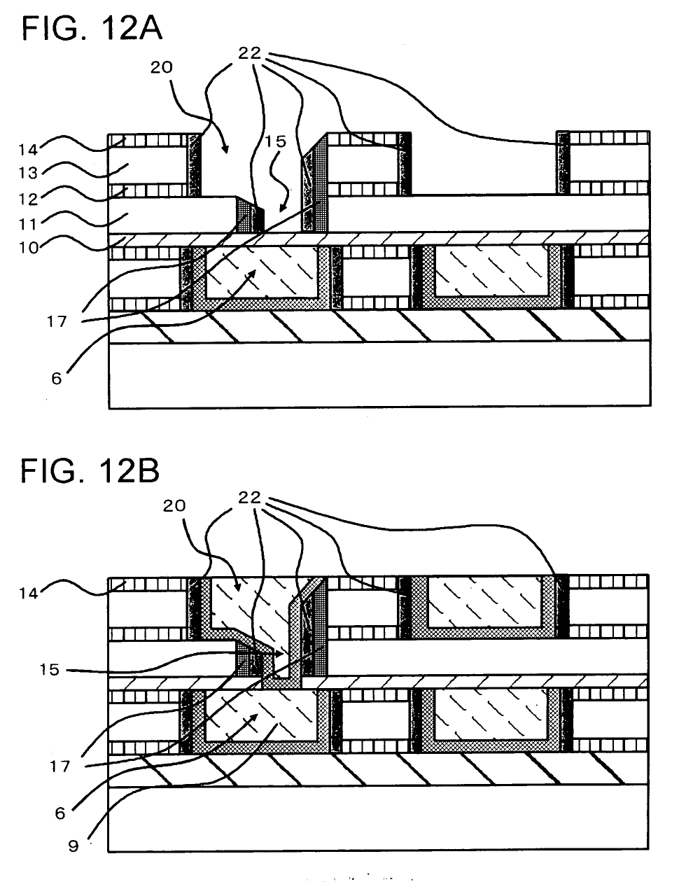

Subsequently, a method for manufacturing the semiconductor device of second embodiment will be described. FIGS. 8A and 8B, FIGS. 9A and 9B, FIGS. 10A and 10B, FIGS. 11A and 11B, and FIGS. 12A and 12B are cross-sectional views, schematically illustrating a procedure for manufacturing a semiconductor device in first embodiment.

The method for manufacturing the semiconductor device according to second embodiment includes, similarly as in the method for manufacturing the semiconductor device according to first embodiment: forming the connection hole (via hole 15) in the interlayer insulating film; forming the first insulating film (insulating film 16 for forming the first sidewall) in the inside of the via hole 15 and then carrying out an etchback so as to leave the insulating film 16 for forming the first sidewall over the side surface of the via hole 15; forming the second interconnect trench 20 coupled to the via hole 15 in the interlayer insulating film; forming the second insulating film (insulating film 21 for forming the second sidewall) in the inside of the via hole 15 and in the inside of the second interconnect trench 20; and carrying out an etchback so as to leave the second insulating film (insulating film 21 for forming the second sidewall) over the first insulating film (insulating film 16 for forming the first sidewall) of the side surface of the via hole 15 and over the side surface of the second interconnect trench 20 to form the first sidewall (first sidewall 17 and the second sidewall 22) including the first insulating film (insulating film 16 for forming the first sidewall) and the second insulating film (insulating film 21 for forming the second sidewall) over the side surface of the via hole 15 and to form the second sidewall (second sidewall 22) including the second insulating film (insulating film 21 for forming the second sidewall) over the side surface of the second interconnect trench 20. In such case, the first sidewall (first sidewall 17 and second sidewall 22) is formed by carrying out an etchback process to partially leave the first insulating film (insulating film 16 for forming the first sidewall) and the second insulating film (insulating film 21 for forming the second sidewall).

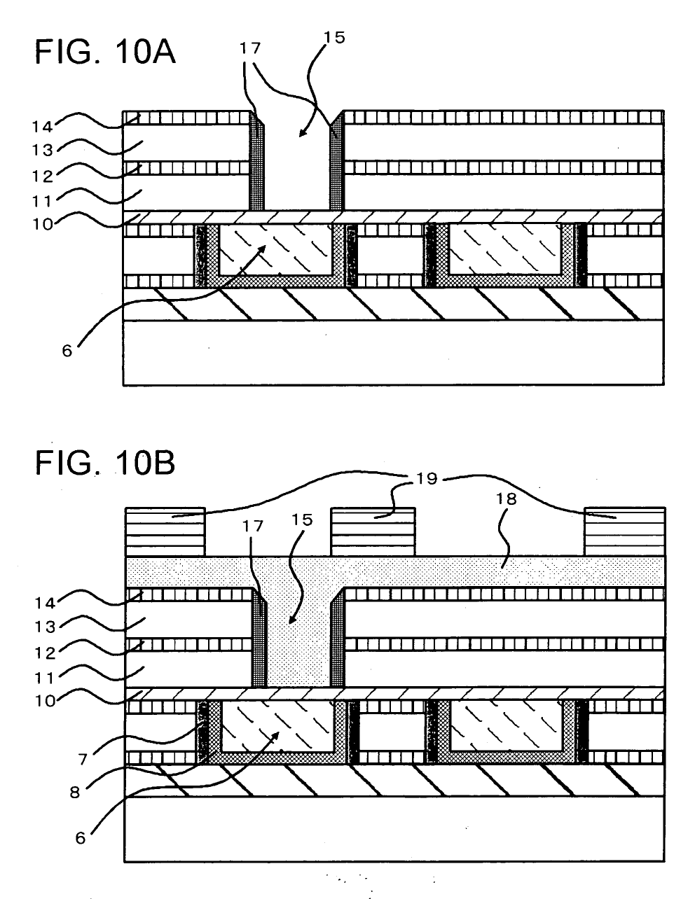

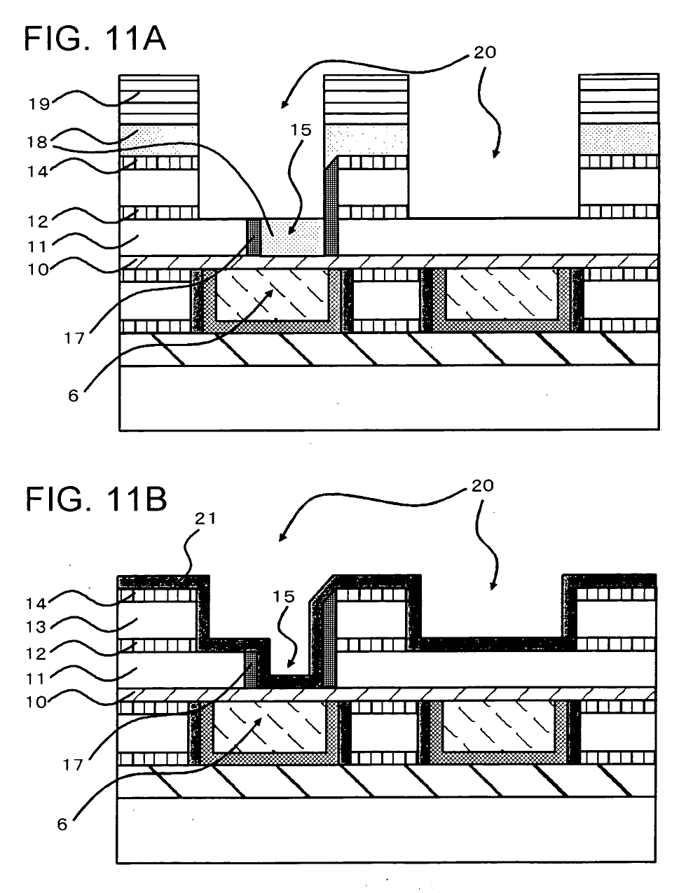

The method for manufacturing the device of second embodiment as illustrated in FIGS. 8A and 8B, FIGS. 9A and 9B, FIGS. 10A and 10B, FIGS. 11A and 11B, and FIGS. 12A and 12B are similar to the method for manufacturing the device of first embodiment as illustrated in FIGS. 2A and 2B, FIGS. 3A and 3B, FIGS. 4A and 4B, FIGS. 5A and 5B, and FIGS. 6A and 6B, except the following features. The differences of second embodiment from first embodiment are a position of the via hole 15 as shown in FIG. 10A and a position of the second interconnect trench 20 relative to the via hole 15 as shown in FIG. 11A. In this operation, the formation of the via hole 15 and the second interconnect trench is carried out so that a portion of the circumference of the via hole 15 overlaps with a portion of the circumference of the second interconnect trench 20 (or both portions are in a relation of “on-line”). More specifically, when the second interconnect trench 20 is formed, an elongated portion of the circumference (first sidewall 17) of the via hole 15 along the direction normal to the substrate shares the circumference of the second interconnect trench 20. As described above, a portion of the circumference of the via hole 15 and a portion of the circumference of the second interconnect trench 20 are formed to be seamless therebetween.

In addition, in the present embodiment, a cross-sectional geometry of the upper portion of the second sidewall 22 over the side surface of the second interconnect trench 20 partially includes a corner. In addition, a portion of the upper portion of the sidewall (the via hole 15 and the second sidewall 22) on the side surface of the via hole 15 and a portion of the upper portion of the second sidewall 22 on the side surface of the second interconnect trench 20 are tapered.

In the operation as illustrated in FIG. 10A, the position of the via hole 15 is adjusted by adjusting the position of the opening in the photo resist. In addition, in the operation as illustrated in FIG. 11A, the position of the second interconnect trench 20 is adjusted by adjusting the position of the opening in the photo resist 19. In this way, as shown in FIG. 7, the end of the via hole 15 is protruded outside of the end of the second layer interconnect (second interconnect trench 20) due to an misalignment or the like.

Advantageous effects of the present embodiment will be described.

The side surface portions of the via hole 15 and the second interconnect trench 20 are provided in common with the thicker sidewall extending the entire side surface portions (first sidewall 17 and second sidewall 22). Thus, device in second embodiment exhibits longer life for TDDB (time dependent dielectric breakdown). In addition, since the thicker portion of the sidewall is limited to the portion in vicinity of the via hole 15, reduced parasitic capacitance of the second interconnect trench 20 can be maintained.

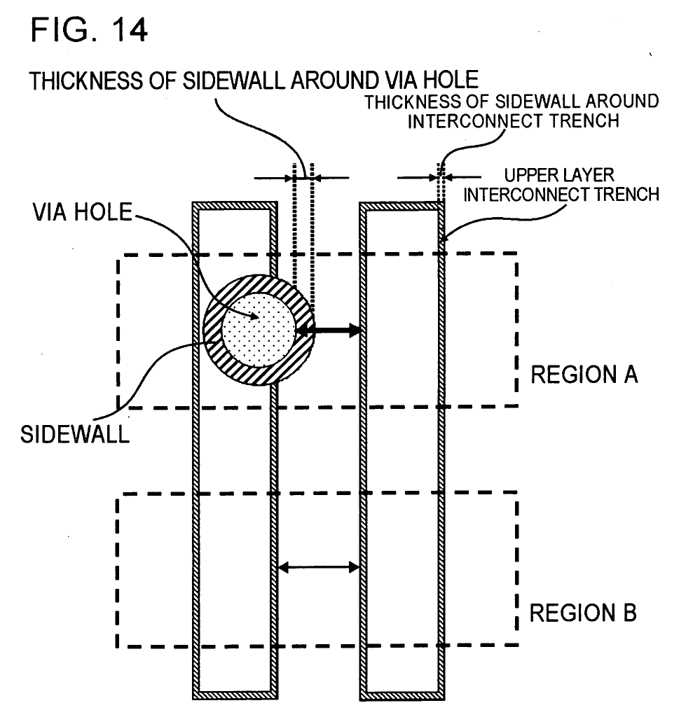

The advantageous effects of the second embodiment will be further described in reference to FIG. 14. FIG. 14 schematically illustrates two of the second copper interconnects 24 in the second layer, the via hole 15 the first sidewall 17 and the second sidewall 22. In FIG. 14, a region A illustrates a region between the interconnects where the via hole is provided, and a region B illustrates a region between the interconnects where no via hole is provided. In the region A, increased thickness of the sidewall on the side surface of the via hole is provided. Thus, this allows providing a reduced leakage current and improved TDDB resistance. On the other hand, in the region B that occupies the greater part of the interconnect, the reduced thickness of the sidewall is provided. Thus, the parasitic capacitance between the interconnects can be reduced. In such case, in the region B, sufficient distance between the interconnects can be ensured. Therefore, no problem is occurred in relation with the leakage current and the TDDB resistance, even if the thickness of the sidewall is smaller.

### Examples

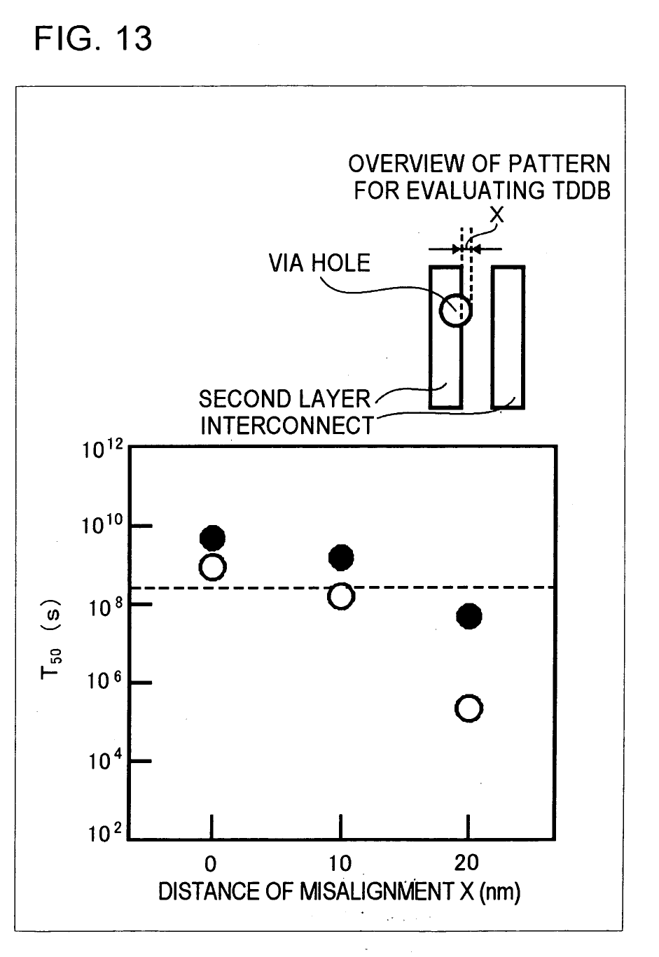

In the present example, evaluations on the TDDB resistance between Cu interconnects were conducted for a sample 1 and a sample 2, which were manufactured as described below in example and comparative example, respectively (the temperature was elevated to 150 degrees C., and an electric voltage having a voltage level of up to 3.6 V that does not cause a breakdown of the insulating film was continuously applied, and under such condition, the time required for causing the breakdown was obtained). In addition to above, the linewidth of the Cu interconnect was selected to be 70 nm, and the distance between the interconnects was selected to be 70 nm. In addition, the size of the via hole was selected to be 70 nmΦ. The results of the evaluation of the TDDB are shown in FIG. 13. In FIG. 13, black dots represent the results of example, and white dots represent the results of comparative example.

### (1) Example

A device having a structure corresponding to the structure according to first embodiment, in which a via and an interconnect forms a seamless interconnect, was manufactured according to the above-described manufacturing process to present the above-described sample 1, and further, a structure corresponding to the structure according to second embodiment, in which the via was misaligned with a misalignment distance, was also manufactured. In sample 1, the thickness of the sidewall in the via hole was selected to be larger than the thickness of the sidewall in the second layer interconnect.

### (2). Comparative Example

A device having a structure, which was similar to the structure of the sample 1 except that the thickness of the sidewall in the via hole was substantially the same as the thickness of a sidewall in the second layer interconnect, was manufactured to present the above-described sample 2.

Advantageous effects of the semiconductor device of the present embodiment will be described in reference to FIG. 13 by comparing with comparative example. FIG. 13 shows distance dependency of TDDB lifetime over the misalignment between interconnect-via as results of the TDDB evaluation.

As shown in comparative example, when the thickness of the sidewall formed on the side surface in the via hole is the substantially same as the thickness of a sidewall formed on the side surface in the second layer interconnect, a smaller misalignment distance causes a deterioration of the TDDB life, failing to reach to the target value of the TDDB life. On the other hand, if the thicknesses of both sidewall insulating films disposed on the side surface in the via hole and on the side surface in the second layer interconnect trench are increased in order to prevent the above-described deterioration, a dielectric constant of the insulating film existing between the second layer interconnects is increased to provide an increased parasitic capacitance.

On the contrary, as shown in example, increased thickness of the sidewall in the via hole and increased thickness of the sidewall in the inside of the second layer interconnect trench allows providing an improved TDDB life. Even if an electric field is concentrated on the portion where the via hole extends beyond the interconnect, a generation of leakage current in such portion or a tendency for easily deteriorating the dielectric withstand voltage can be avoided. Therefore, the semiconductor device having an improved reliability can be achieved. At this time, a ratio of the portion of the sidewall having higher specific dielectric constant in the space portion can be reduced when the interconnect having a constant line width is formed, providing increased ratio of the low dielectric constant film. As a result, reduced parasitic capacitance between interconnects can be obtained in the present embodiment.

While the preferred embodiments of the present invention have been described above in reference to the annexed figures, it should be understood that the disclosures above are presented for the purpose of illustrating the present invention, and various modifications other than that described above are also available.

For example, while the case of employing the dual-layered interconnect has been described in first embodiment, an multiple-layered interconnect is generally employed in actually products, and if a triple- or more-layered copper interconnect layer is formed, the processes illustrated in FIG. 2A to FIG. 6B are repeated for multiple cycles. In addition, an operation for forming a pad for bonding in the assembly is additionally carried out, and the detailed description on such operation is not made here.

In the present embodiment, the positional relation between the via hole 15 and the second interconnect trench 20 is not particularly limited to any specific relation. As described above, the circumference of via hole 15 may overlap with, or in relation of on-line with the circumference of the second interconnect trench 20, or may be provided inside of or outside of the circumference of the second interconnect trench. For example, if the positional relation is the on-line relation in the present embodiment, the sidewall in the via hole 15 is composed of two layers, and a portion of the sidewall in the second interconnect trench 20 is composed of a single layer or two layers. If the positional relation is not the on-line relation, the sidewall in the via hole 15 is composed of two layers, and the sidewall in the second interconnect trench 20 is composed of a single layer. In addition, in the present embodiment, the diameter of the via hole 15 is not particularly limited in relation to-the second interconnect trench 20, and the diameter of the via hole may be substantially equivalent to, or larger than, or smaller than, the width of the second interconnect trench 20.

For example, a silicon oxide film, a silicon nitride film or a phosphosilicate glass (PSG) film and the like may be employed for the first interlayer insulating film 2. The thickness of the first interlayer insulating film 2 may be, for example, within a range of from 200 nm to 800 nm. Materials and the thickness of the first etch stop film 3 are not particularly limited, as long as the first etch stop film 3 serves as an etch stop film for the first interconnect trench 6. The presence of the first etch stop film 3 may be utilized to reduce the variation in the depth of the formed trench under a certain variation, when the interconnect is embedded in the trench. The first etch stop film 3 is configured of, for example, SiC, SiCN, SiOC, or a multiple-layered structure composed thereof. In addition, the thickness of the first etch stop film 3 may be, for example, 20 nm to 70 nm.

The materials for the second interlayer insulating film 4 and the third interlayer insulating film 13 is not particularly limited to any specific material, as long as a porous insulating film having low dielectric constant or namely a porous low-k film is employed. Typical porous low-k film may be a film containing silicon (Si) and oxygen (O) as constituent elements, or a film containing Si, carbon (C), O and hydrogen (H) as constituent elements. In addition, the thickness of the second interlayer insulating film 4 may be, for example, 80 nm to 150 nm. The thickness of the third interlayer insulating film 13 may be, for example, 50 nm to 120 nm.

In addition, the interlayer insulating film may be composed of a low dielectric constant film such as a polyorganosiloxane film, a hydrogenating siloxane film, or porosified films of these films. In addition to above, the material of the second interlayer insulating film 4 and the material of the third interlayer insulating film 13 may be the same, or different. The specific dielectric constant of the low dielectric constant film may be, for example, equal to or lower than 3.5, and preferably equal to or lower than 3.

The material for the via interlayer insulating film 11 is not particularly limited to any specific material, and may be, for example, a non-porous film containing Si, C, O and H as constituent elements. The thickness of the via interlayer insulating film 11 may be, for example, 50 nm to 120 nm.

The material for the first cap insulating film 5 and the second cap insulating film 14 is not particularly limited, and for example, a film containing Si, C and O as constituent elements may be employed. In addition, the thickness of the first cap insulating film 5 may be, for example, 10 nm to 50 nm. The thickness of the second cap insulating film 14 may be 30 nm to 60 nm.

The materials for the sidewall 7 of first layer, the first sidewall 17 and the second sidewall 22 are not particularly limited to any specific material, as long as the films are made of dense insulating films. An insulating film without pore may also be employed. Such dense insulating film serves as a protective film. More specifically, the portions contacting with the second interlayer insulating film 4, via interlayer insulating film 11 and, the first interconnect trench 6, the via hole 15 and the second interconnect trench 20 of the third interlayer insulating film 13, may be covered with a chemically stable film. In particular, the porous low-k film can be protected.

The available material for the first insulating film sidewall 7, the first sidewall 17 and the second sidewall 22 may be, for example, a film containing Si and C as constituent elements, a film containing Si, C and O as constituent elements, a film containing Si, C and a N as constituent elements and a film containing Si and O as constituent elements. For example, a material containing a SiC, a SiOC, a silicon dioxide (SiO₂) or a SiCN may be employed.

In addition, the thickness of the first sidewall 17 may be, for example, 2 nm to 20 nm. The thickness of the first sidewall 17 may be, for example, 3 nm to 40 nm. The thickness of the second sidewall 22 may be, for example, 2 nm to 20 nm.

In addition to above, the method for manufacturing these films is not particularly limited, and, for example, a chemical vapor deposition (CVD) process, or a coating process may be utilized.

In addition to above, in the present embodiment, it is configured that the thicknesses of the insulating film sidewalls on the side surface of the via hole and on the portion of the side surface of the interconnect trench extending from the via hole to the upper interconnect are larger than the thickness of the insulating film sidewall formed on the portion of interconnect trench except where the via hole is present. This allows preventing deteriorations of leakage characteristic, TDDB or the like, by presenting the non-porous low-k material having larger thickness between between the via hole with the shortest distance and the space portion of the adjacent interconnect.

While tantalum (Ta) is illustrated for the barrier metal film in the present embodiment, the material for the barrier metal film is not limited thereto, and for example, when the interconnect is composed of a metallic element of Cu as a major constituent, a refractory metal or a nitride thereof, such as a tantalum nitride (TaN), a titanium (Ti), a titanium nitride (TiN), a tungsten carbonitride (WCN), a ruthenium (Ru) or the like, or a multiple-layered film thereof, may be employed. In addition, the above-described metallic film may be also employed for a barrier metal in a contact plug that employs tungsten as a major constituent.

In addition, when the configuration of the present invention is applied to the interconnect structure with the damascene process, increased advantageous effect of the present invention becomes is obtained. More specifically, the metallic regions in the present invention may be formed by a single damascene process or a dual damascene process.

The single damascene process may contain the following operations:
(a) an operation for forming a first interconnect composed of a metallic film on or over a semiconductor substrate;
(b) an operation for forming a first interlayer insulating film over the entire semiconductor substrate so as to cover the first interconnect;
(c) an operation for selectively removing the first interlayer insulating film to form a connection hole extending to an upper surface of the first interconnect;
(d) an operation for forming a metallic film to fill the connection hole after a barrier metal film is formed to cover an inner surface of the connection hole;
(e) an operation for removing a metallic film formed outside of the connection hole;
(f) an operation for forming the second interlayer insulating film over the entire semiconductor substrate so as to cover the metallic film formed in the connection hole;
(f) an operation for selectively removing the second interlayer insulating film to form an interconnect trench having the bottom surface where exposed metallic film is formed in the connection hole;
(g) an operation for forming a metallic film to fill the interconnect trench after a barrier metal film is formed to cover an inner surface of the interconnect trench; and
(h) an operation for removing a metallic film formed outside of the interconnect trench to form a second interconnect.

The semiconductor device according to the present invention and the method for manufacturing may be applied to such process by applying the whole of or a part of the first and the second interconnects and the connection hole to the “metallic region” in the present invention. Here, a part of the operations of the above-described (a) to (h) may not be conducted.

The dual damascene process may contain the following operations.
(a) an operation for forming a first interconnect composed of a metallic film on or over a semiconductor substrate;
(b) an operation for forming a first interlayer insulating film over the entire semiconductor substrate so as to cover the first interconnect;
(c) an operation for selectively removing the first interlayer insulating film to form a connection hole extending to an upper surface of the first interconnect and an interconnect trench coupling to the upper portion of the connection hole;
(d) an operation for forming a metallic film to fill the connection hole and the interconnect trench after a barrier metal film is formed to cover an inner surface of the connection hole and the interconnect trench; and
(e) an operation for removing a metallic film formed outside of the interconnect trench to form a second interconnect.

The semiconductor device according to the present invention and the method for manufacturing may be applied to such process by applying the whole of or a part of the first and the second interconnects and the connection hole to the “metallic region” in the present invention. Here, a part of the operations of the above-described (a) to (e) may not be conducted.

The interconnect structure formed in the above-described damascene process has a configuration including: a semiconductor substrate; a first interconnect formed on or over the semiconductor substrate; a coupling plug provided so as to be coupled to the first interconnect; and a second interconnect provided so as to be coupled to the coupling plug.

In addition, while the exemplary implementation of the semiconductor device provided with the copper interconnect has been described in the above-described embodiment, the interconnect may be primarily composed of a copper-containing metallic material. In addition, the process for forming the interconnect is not limited to a plating process, and for example, a CVD process may alternatively be employed.

In the present embodiment, the material for the metallic interconnect and the material for the contact plug may contain Cu as a major constituent. In order to provide an improved reliability of the metallic interconnect material, a metallic element except Cu may be contained in a member composed of Cu, or a metallic element except Cu may be formed in an upper surface or a side surface of Cu.

The semiconductor substrate is a substrate or a workpiece containing a semiconductor device configured therein, and is not particularly limited to a workpiece formed on a single crystalline silicon substrate, but includes silicon on insulator (SOI) having a thin film of a semiconductor formed on an insulating material, silicon germanium on insulator (SGOI), a workpiece having a semiconductor element formed on a hybrid substrate, thin film transistor (TFT), a substrates for manufacture liquid crystal, and the like.

It is apparent that the present invention is not limited to the above embodiment, and may be modified and changed without departing from the scope and spirit of the invention.

What is claimed is:

1. A semiconductor device, comprising:
a substrate;
an interlayer insulating film provided over said substrate;
an interconnect composed of a metallic film provided in an interconnect trench and a plug composed of a metallic film provided in a connection hole coupled to said interconnect trench, said interconnect and said plug being provided in said interlayer insulating film;
a first sidewall provided over a side surface of said connection hole; and
a second sidewall provided over a side surface of said interconnect trench,
wherein a thickness of said first sidewall in vicinity of a bottom of the side surface of said connection hole is larger than a thickness of said second sidewall in vicinity of a bottom of the side surface of said interconnect trench.

2. The semiconductor device as set forth in claim 1, wherein said first sidewall has a multiple-layered structure.

3. The semiconductor device as set forth in claim 1, wherein a cross-sectional geometry of an upper portion of said second sidewall has a corner.

4. The semiconductor device as set forth in claim 3, wherein a circumference of an upper portion of said first sidewall is tapered.

5. The semiconductor device as set forth in claim 1, wherein a cross-sectional geometry of an upper portion of said second sidewall partially has a corner.

6. The semiconductor device as set forth in claim 5, wherein the upper portion of said first sidewall and the upper portion of said second sidewall are tapered, respectively.

7. The semiconductor device as set forth in claim 5, wherein a portion of said first sidewall shares a portion of said second sidewall.

8. The semiconductor device as set forth in claim 1, wherein said connection hole and said interconnect trench are formed to be seamless therebetween.

9. The semiconductor device as set forth in claim 1,
wherein said interlayer insulating film includes a first interlayer insulating film and a second interlayer insulating film provided over said first interlayer insulating film,
wherein said connection hole is provided in said first interlayer insulating film, and
wherein said interconnect trench is provided in said second interlayer insulating film.

10. The semiconductor device as set forth in claim 9, wherein said second interlayer insulating film is composed of a porous insulating film.

11. The semiconductor device as set forth in claim 10, wherein said porous insulating film is a porous film containing Si and O as constituent elements, or a porous film containing Si, C, O and H as constituent elements.

12. The semiconductor device as set forth in claim 9, wherein said first interlayer insulating film is a film containing Si, C, O and H as constituent elements.

13. The semiconductor device as set forth in claim 1, wherein said first sidewall is composed of a material containing a SiC, a SiOC, a SiO₂ or a SiCN.

14. The semiconductor device as set forth in claim 1, wherein said second sidewall is composed of a material containing a SiC, a SiOC, a SiO₂ or a SiCN.

15. A method for manufacturing a semiconductor device, comprising:
forming an interlayer insulating film over a substrate;
forming an interconnect trench and a connection hole coupled to said interconnect trench in said interlayer insulating film;
forming a first sidewall over a side surface of said connection hole and forming a second sidewall over a side surface of said interconnect trench; and
forming a metallic film in said interconnect trench and in said connection hole,
wherein said forming the first and the second sidewalls includes forming said sidewalls so that a thickness of said first sidewall in vicinity of a bottom of the side surface of said connection hole is larger than a thickness of said second sidewall in vicinity of a bottom of the side surface of said interconnect trench.

16. The method for manufacturing the semiconductor device as set forth in claim 15, wherein said step of forming the first and the second sidewalls includes:
forming said connection hole in said interlayer insulating film;
forming a first insulating film in the inside of said connection hole and then carrying out an etchback so as to leave said first insulating film over the side surface of said connection hole;
forming said interconnect trench coupled to said connection hole in said interlayer insulating film;
forming a second insulating film in the inside of said connection hole and in the inside of said interconnect trench; and
carrying out an etchback so as to leave said second insulating film over said first insulating film of said side surface of said connection hole and over the side surface of said interconnect trench to form said first sidewall including said first insulating film and said second insulating film over said side surface of said connection hole and to form said second sidewall including said second insulating film over said side surface of said interconnect trench.

17. The method for manufacturing the semiconductor device as set forth in claim 15, wherein said connection hole and said interconnect trench are formed to be seamless therebetween.

18. The method for manufacturing the semiconductor device as set forth in claim 15,
wherein said interlayer insulating film includes a first interlayer insulating film and a second interlayer insulating film formed over said first interlayer insulating film, and
wherein said connection hole is formed in said first interlayer insulating film and said interconnect trench is formed in said second interlayer insulating film.

19. The method for manufacturing the semiconductor device as set forth in claim 18, wherein said second interlayer insulating film is composed of a porous insulating film.

20. The method for manufacturing the semiconductor device as set forth in claim 19, wherein said porous insulating film is a porous film containing Si and O as constituent elements, or a porous film containing Si, C, O and H as constituent elements.

21. The method for manufacturing the semiconductor device as set forth in claim 18, wherein said first interlayer insulating film is a film containing Si, C, O and H as constituent elements.

22. The method for manufacturing the semiconductor device as set forth in claim 15, wherein said first sidewall is composed of a material containing a SiC, a SiOC, a SiO₂ or a SiCN.

23. The method for manufacturing the semiconductor device as set forth in claim 15, wherein said second sidewall is composed of a material containing a SiC, a SiOC, a SiO₂ or a SiCN.
